(19) United States
(12) Patent Application Publication
(10) Pub. No.: US 2025/0140533 A1
(43) Pub. Date: May 1, 2025

(54) SUBSTRATE SUPPORT DEVICE AND METHOD OF CONTROLLING PREVENTION OF LEAKAGE OF TEMPERATURE CONTROL FLUID

(71) Applicant: SEMES CO., LTD., Cheonan-si (KR)

(72) Inventors: Soon Cheon CHO, Cheonan-si (KR); Joon Hee LEE, Cheonan-si (KR); Kyung Hwa JUNG, Cheonan-si (KR); Ji Chul KANG, Cheonan-si (KR); Jung Hoon PARK, Cheonan-si (KR); Dong Uk KIM, Cheonan-si (KR)

(73) Assignee: SEMES CO., LTD., Cheonan-si (KR)

(21) Appl. No.: 18/796,952

(22) Filed: Aug. 7, 2024

(30) Foreign Application Priority Data
Oct. 31, 2023 (KR) 10-2023-0147717

(51) Int. Cl. H01J 37/32; H01L 21/683

(52) U.S. Cl. CPC H01J 37/32724; H01L 21/6833; H01J 2237/002; H01J 2237/2007; H01J 2237/334

(57) ABSTRACT

Disclosed are a substrate support device and a method of controlling prevention of leakage of temperature control fluid. In a substrate support device that controls temperature through supply of temperature control fluid, a sealing member configured to be actively controlled in volume expansion taking into consideration a difference in coefficient of expansion between a fluid supply block supplying the temperature control fluid and an electrostatic chuck due to the materials thereof is employed, thereby preventing leakage of the temperature control fluid.

### CROSS REFERENCE TO RELATED APPLICATION

The present application claims priority to Korean Patent Application No. 10-2023-0147717, filed on Oct. 31, 2023, the entire contents of which are herein incorporated by reference.

### BACKGROUND OF THE INVENTION

### Field of the Invention

The present invention relates to a substrate support device and a method of controlling prevention of leakage of temperature control fluid, and more particularly, to technology for preventing leakage of temperature control fluid by employing sealing member that is actively controlled in volume expansion taking into consideration a difference in coefficient of expansion between a fluid supply block supplying the temperature control fluid and an electrostatic chuck due to the materials thereof in a substrate support device that controls temperature through supply of the temperature control fluid.

### Description of the Related Art

A process of manufacturing semiconductors or display panels is performed in a state in which a substrate support device such as an electrostatic chuck supports a substrate such as a wafer.

For example, an etching process or a cleaning process is performed using various processing gases or processing liquids in a state in which a substrate support device supports a substrate.

Such a process requires a temperature change between high temperature and low temperature depending on process conditions. Temperatures of a substrate to be processed and a substrate processing apparatus are controlled by supplying temperature control fluid, such as a heat transfer medium or coolant, to the substrate processing apparatus.

In order to prevent leakage of temperature control fluid, a sealing member such as an O-ring is mounted to a connection portion between supply flow paths or the like. In spite of employment of such a sealing member, if components made of different materials are in contact with and coupled to each other, a gap may be created therebetween upon a sudden change in temperature due to a difference in coefficient of expansion therebetween, and temperature control fluid may leak through the gap.

In an example, in order to supply temperature control fluid to an electrostatic chuck of a substrate processing apparatus, a fluid supply block configured to supply the temperature control fluid is located in contact with the lower surface of the electrostatic chuck, and this fluid supply block is made of a material such as, for example, polyetheretherketone (PEEK). Upon a sudden change in temperature, a gap may be created between the electrostatic chuck and the fluid supply block due to different materials thereof and a resultant difference in coefficient of expansion therebetween. However, the created gap may not be sufficiently blocked by a sealing member occupying a fixed area, thus causing leakage of the temperature control fluid.

Further, in the case in which cryogenic fluid is supplied, an O-ring fastened to the fluid supply block may not achieve sufficient sealing due to a difference in coefficient of expansion between the O-ring and the fluid supply block, thus causing leakage of the cryogenic coolant.

### SUMMARY OF THE INVENTION

The present invention has been made to solve the above problems, and it is an object of the present invention to provide technology for preventing leakage of temperature control fluid by employing a sealing member that is actively controlled in volume expansion taking into consideration a difference in coefficient of expansion between a fluid supply block supplying a heat transfer medium or coolant as the temperature control fluid and an electrostatic chuck due to different materials thereof or a difference in coefficient of expansion between the fluid supply block and the sealing member due to different materials thereof in a substrate support device.

It is another object of the present invention to solve a problem of leakage of fluid between a fluid supply block, which is made of, for example, polyetheretherketone (PEEK), and an electrostatic chuck, which is caused because a gap is created therebetween upon a sudden change in temperature due to different materials thereof and a resultant difference in coefficient of expansion therebetween and a sealing member occupying a fixed area is not capable of sufficiently block the created gap.

In addition, it is still another object of the present invention to solve a cryogenic coolant leakage problem, which is caused because, when cryogenic fluid is supplied, an O-ring fastened to the fluid supply block is not capable of achieving sufficient sealing due to a difference in coefficient of expansion between the O-ring and the fluid supply block.

The objects to be accomplished by the invention are not limited to the above-mentioned objects, and other objects and advantages not mentioned herein may be understood from the following description.

In accordance with an aspect of the present invention, the above and other objects can be accomplished by the provision of a substrate support device including an electrostatic chuck configured to support a substrate, the electrostatic chuck including therein a flow path of temperature control fluid for temperature control, a body member configured to support the electrostatic chuck, a fluid supply block mounted in the body member, the fluid supply block including a temperature control fluid supply path formed therein to supply the temperature control fluid to the flow path in the electrostatic chuck, a sealing member mounted to the fluid supply block, the sealing member including an air injection space defined therein, the sealing member being configured to expand due to injection of air into the air injection space, and an air supply unit configured to inject air into the sealing member.

Preferably, the substrate support device may further include a controller configured to control, based on a difference in temperature between the electrostatic chuck and the fluid supply block or a difference in temperature between the fluid supply block and the sealing member, the air supply unit to inject air into the sealing member to expand the sealing member.

Further, the air supply unit may include an air movement path configured to supply air to the sealing member, an air supply device configured to supply air to the air movement path, and an air injection control valve disposed on the air movement path to control supply of air.

Furthermore, the air supply unit may further include a pressure measurement part configured to measure pressure of air supplied through the air movement path, and the controller may control injection of air into the sealing member based on a pressure value measured by the pressure measurement part.

In an example, the air supply unit may further include a supply air movement path configured to supply air to the sealing member, an air injection control valve disposed on the supply air movement path to control supply of air to be injected, a control air movement path configured to control air pressure in the sealing member, an air pressure control valve disposed on the control air movement path to control pressure of air supplied to the sealing member, a discharge air movement path configured to discharge air from the sealing member, and an air discharge control valve disposed on the discharge air movement path to control discharge of air from the sealing member.

In an example, the air supply unit may further include an air heater configured to control temperature of air to be supplied, and the controller may control the air heater to control temperature of air to be injected according to a degree of expansion of the sealing member.

In an example, the fluid supply block may include a heat transfer medium inlet configured to supply a heat transfer medium to the electrostatic chuck and a heat transfer medium outlet configured to discharge the heat transfer medium from the electrostatic chuck, and the sealing member may include a sealing member mounted to the heat transfer medium inlet and a sealing member mounted to the heat transfer medium outlet.

In an example, the fluid supply block may include a coolant inlet configured to supply coolant to the electrostatic chuck and a coolant outlet configured to discharge the coolant from the electrostatic chuck, and the sealing member may include a first sealing portion fastened to the coolant inlet, the first sealing portion including a first air injection space defined therein, the first sealing portion being configured to expand due to injection of air into the first air injection space, a second sealing portion fastened to the coolant outlet, the second sealing portion including a second air injection space defined therein, the second sealing portion being configured to expand due to injection of air into the second air injection space, and a connection portion configured to interconnect the first sealing portion and the second sealing portion.

In an example, the connection portion of the sealing member may include a connection space defined therein to interconnect the first air injection space in the first sealing portion and the second air injection space in the second sealing portion and an air injection port connected to the air supply unit to supply air to the connection space or to discharge air from the connection space.

In an example, the air supply unit may further include an air heater configured to control temperature of air supplied through the air movement path, and the controller may control the air heater to control temperature of air injected into the sealing member.

In accordance with another aspect of the present invention, there is provided a method of controlling prevention of leakage of temperature control fluid, the method including a temperature control fluid supply step of supplying, by a fluid supply block, temperature control fluid to control temperature of an electrostatic chuck or a substrate or to cool the electrostatic chuck or the substrate, an air supply step of supplying, by an air supply unit, air to a sealing member based on a difference in temperature between the electrostatic chuck and the fluid supply block or a difference in temperature between the fluid supply block and the sealing member, and a sealing step of expanding the sealing member to prevent leakage of the temperature control fluid.

Preferably, the air supply step may include a temperature difference determination step of determining, by a controller, a difference in temperature between the electrostatic chuck and the fluid supply block or a difference in temperature between the fluid supply block and the sealing member, a condition setting step of setting, by the controller, conditions for an amount and pressure of air injected to expand the sealing member based on the difference in temperature, and an air injection step of controlling, by the controller, the air supply unit under the set conditions to inject air into the sealing member.

Further, the sealing step may include an air pressure control step of acquiring, by the controller, a pressure measurement value of air injected into the sealing member and controlling, by the controller, the air supply unit based on the pressure measurement value and a set pressure range to control air pressure in the sealing member.

In an example, in the temperature control fluid supply step, the fluid supply block may supply a heat transfer medium as the temperature control fluid to a flow path of the electrostatic chuck through a heat transfer medium inlet. The air supply step may include a temperature difference determination step of determining, by the controller, a difference in temperature between the electrostatic chuck and the fluid supply block or a difference in temperature between the fluid supply block and the sealing member according to supply of the heat transfer medium, a condition setting step of setting, by the controller, conditions for one or more of an amount, pressure, and temperature of air injected to expand a sealing member mounted to the heat transfer medium inlet of the fluid supply block based on the difference in temperature according to supply of the heat transfer medium, and an air injection step of opening, by the controller, an air injection control valve based on the difference in temperature and controlling, by the controller, an air supply device under the set conditions to inject air into the sealing member through a supply air movement path.

In an example, in the sealing step, if air pressure in the sealing member exceeds a set pressure range, the controller may control an air pressure control valve disposed on a control air movement path to control air injected into the sealing member.

In an example, in the temperature control fluid supply step, the fluid supply block may discharge the heat transfer medium as the temperature control fluid from the flow path of the electrostatic chuck through a heat transfer medium outlet. The air supply step may further include a temperature difference determination step of determining, by the controller, a difference in temperature between the electrostatic chuck and the fluid supply block or a difference in temperature between the fluid supply block and the sealing member according to discharge of the heat transfer medium, a condition setting step of setting, by the controller, conditions for one or more of an amount, pressure, and temperature of air injected to expand a sealing member mounted to the heat transfer medium outlet of the fluid supply block based on the difference in temperature according to discharge of the heat transfer medium, and an air injection step of opening, by the controller, the air injection control valve based on the difference in temperature and controlling, by the controller, the air supply device under the set conditions to inject air into the sealing member through the supply air movement path.

In an example, in the temperature control fluid supply step, the fluid supply block may supply coolant as the temperature control fluid to a flow path of the electrostatic chuck through a coolant inlet and may discharge the coolant from the flow path of the electrostatic chuck. The air supply step may include a temperature difference determination step of determining, by the controller, a difference in temperature between the electrostatic chuck and the fluid supply block or a difference in temperature between the fluid supply block and the sealing member according to supply and discharge of the coolant, a condition setting step of setting, by the controller, conditions for one or more of an amount, pressure, and temperature of air injected to expand a sealing member mounted to the coolant inlet of the fluid supply block based on the difference in temperature according to supply and discharge of the coolant, and an air injection step of opening, by the controller, an air injection control valve based on the difference in temperature and controlling, by the controller, an air supply device under the set conditions to inject air into the sealing member through a supply air movement path.

In an example, in the air injection step, air may be injected into a connection portion of the sealing member, and may be supplied to a first sealing portion and a second sealing portion through the connection portion, and in the sealing step, the first sealing portion and the second sealing portion may expand to prevent leakage of the coolant.

In an example, in the sealing step, if air pressure in the sealing member exceeds a set pressure range, the controller may control an air pressure control valve disposed on a control air movement path to control air injected into the first sealing portion and the second sealing portion.

In accordance with still another aspect of the present invention, there is provided a substrate support device including an electrostatic chuck configured to support a substrate, the electrostatic chuck including a first flow path and a second flow path formed therein so as to correspond to a heat transfer medium and coolant as temperature control fluid for temperature control, a body member configured to support the electrostatic chuck, a fluid supply block mounted in the body member, the fluid supply block being provided with a temperature control fluid supply path including a heat transfer medium supply path, including a heat transfer medium inlet and a heat transfer medium outlet to supply and discharge the heat transfer medium to and from the first flow path of the electrostatic chuck, and a coolant supply path, including a coolant inlet and a coolant outlet to supply and discharge the coolant to and from the second flow path of the electrostatic chuck, a sealing member including a first sealing member, mounted to each of the heat transfer medium inlet and the heat transfer medium outlet and including an air injection space defined therein to be controlled in expansion according to injection of air thereinto, and a second sealing member, including a first sealing portion mounted to the coolant inlet and including a first air injection space defined therein, a second sealing portion mounted to the coolant outlet and including a second air injection space defined therein, and a connection portion interconnecting the first sealing portion and the second sealing portion and including a connection space defined therein so as to be connected to the first air injection space and the second air injection space, the sealing member being configured to be controlled expansion according to injection of air thereinto, an air supply unit including an air movement path, including a supply air movement path configured to supply air to the sealing member, a control air movement path configured to control air pressure in the sealing member, and a discharge air movement path configured to discharge air from the sealing member, an air control valve, including an air injection control valve disposed on the supply air movement path to control supply of air injected, an air pressure control valve disposed on the control air movement path to control pressure of air supplied to the sealing member, and an air discharge control valve disposed on the discharge air movement path to control discharge of air from the sealing member, and an air supply device, including a pressure measurement part configured to measure pressure of air supplied through the air movement path and an air supplier configured to supply air, and a controller configured to control, based on a difference in temperature between the electrostatic chuck and the fluid supply block or a difference in temperature between the fluid supply block and the sealing member, the air supply unit to inject air into the sealing member to expand the sealing member.

### BRIEF DESCRIPTION OF THE DRAWINGS

The above and other objects, features, and other advantages of the present invention will be more clearly understood from the following detailed description taken in conjunction with the accompanying drawings, in which:

FIG. 1 shows an embodiment of a substrate processing apparatus to which a substrate support device according to the present invention is applied;

FIG. 2 shows an embodiment of a fluid supply block of the substrate support device according to the present invention;

FIGS. 3A and 3B show an embodiment of a sealing member according to the present invention;

FIG. 4 shows a configuration diagram of an embodiment of an air supply device of the substrate support device according to the present invention;

FIGS. 5A and 5B show another embodiment of the sealing member according to the present invention;

FIG. 6 shows a flowchart of an embodiment of a method of controlling prevention of leakage of temperature control fluid according to the present invention;

FIGS. 7A to 7C show an embodiment of a leakage prevention control process when a heat transfer medium as the temperature control fluid is supplied in the method of controlling prevention of leakage of temperature control fluid according to the present invention;

FIGS. 8A to 8C show an embodiment of a leakage prevention control process when the heat transfer medium as the temperature control fluid is discharged in the method of controlling prevention of leakage of temperature control fluid according to the present invention;

FIGS. 9A to 9C show an embodiment of a leakage prevention control process when coolant as the temperature control fluid is supplied and discharged in the method of controlling prevention of leakage of temperature control fluid according to the present invention;

FIG. 10 shows a flowchart of another embodiment of the method of controlling prevention of leakage of temperature control fluid according to the present invention;

FIGS. 11A and 11B show an embodiment of a process of controlling air pressure in the sealing member in the method of controlling prevention of leakage of temperature control fluid according to the present invention; and

FIGS. 12A and 12B show an embodiment of a process of discharging air from the sealing member in the method of controlling prevention of leakage of temperature control fluid according to the present invention.

### DETAILED DESCRIPTION OF THE INVENTION

Hereinafter, exemplary embodiments of the present invention will be described in detail with reference to the accompanying drawings, but the present invention is not limited or restricted to the exemplary embodiments.

In order to sufficiently understand the present invention, the operational advantages of the present invention, and the objects to be accomplished by practice of the present invention, it is necessary to refer to the accompanying drawings illustrating the exemplary embodiments of the present invention and content contained in the drawings.

Further, the terminology used herein is for the purpose of describing particular embodiments only and is not intended to be limiting. As used herein, singular forms may be intended to include plural forms as well, unless the context clearly indicates otherwise. Further, in the following description of the embodiments, the terms “comprising,” “including,” or “having” are inclusive and therefore specify the presence of stated features, numbers, steps, operations, elements, components, or combinations thereof, but do not preclude the presence or addition of one or more other features, numbers, steps, operations, elements, components, or combinations thereof.

In the following description of the embodiments of the present invention, a detailed description of known configurations or functions incorporated herein will be omitted when it may unnecessarily obscure the subject matter of the present invention.

The present invention provides technology for preventing leakage of temperature control fluid by employing a sealing member that is actively controlled in volume expansion taking into consideration a difference in coefficient of expansion between a fluid supply block supplying the temperature control fluid and an electrostatic chuck due to the materials thereof in a substrate support device that controls temperature through supply of the temperature control fluid.

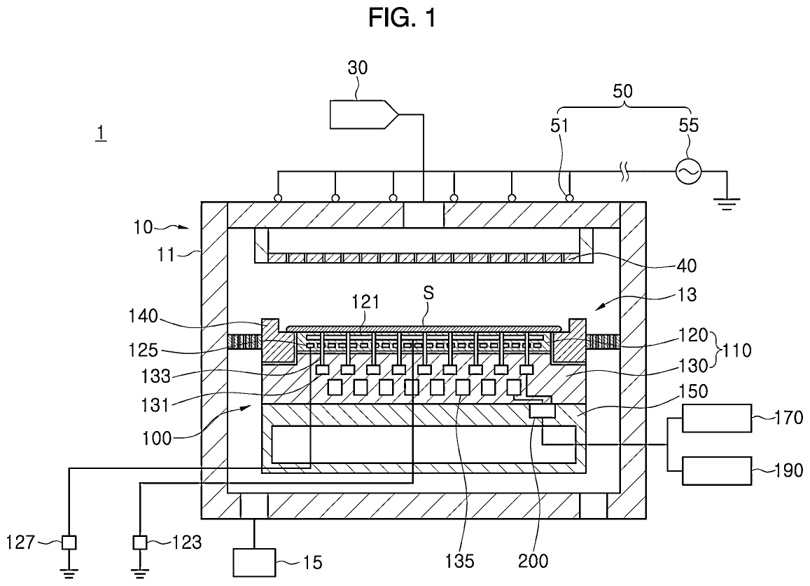

FIG. 1 shows an embodiment of a substrate processing apparatus to which a substrate support device according to the present invention is applied.

The substrate support device 100 according to the present invention may be applied to various substrate processing apparatuses used to process substrates, such as wafers or glass sheets, for manufacture of semiconductors, displays, etc.

The substrate processing apparatus 1 to which the substrate support device 100 according to the present invention is applied may be an apparatus that performs a series of substrate processing processes, including etching, ashing, deposition, and cleaning, in order to manufacture semiconductors. Hereinafter, a dry etcher that performs an etching process among substrate processing apparatuses using plasma will be described as the exemplary embodiment of the present invention.

In this embodiment, the substrate processing apparatus 1 may be configured to perform an etching process using plasma as a process of processing a substrate S. To this end, the substrate processing apparatus 1 may include a process chamber 10, a substrate support device 100, a process gas supply unit 30, a shower head 40, and a plasma generation unit 50.

The process chamber 10 may include a substrate processing space 13 defined therein so as to be capable of being blocked from the outside, and the substrate S may be processed by plasma in the substrate processing space 13. The process chamber 10 may include a chamber main body 11. The chamber main body 11 may be formed to have the substrate processing space 13 therein. The chamber main body 11 may be made of metal. For example, the material of the chamber main body 11 may be aluminum (Al). The chamber main body 11 may be grounded.

At least one exhaust port, which communicates with the substrate processing space 13, may be provided in the bottom of the chamber main body 11, and an exhaust unit 15, which performs exhaust operation, may be connected to the exhaust port. The exhaust unit 15 may include an exhaust line connected to the exhaust port and a vacuum pump connected to the exhaust line. Due to the exhaust operation of the exhaust unit 15, pressure in the substrate processing space 13 may be lowered so that the substrate processing process is performed under the vacuum atmosphere, and by-products generated during the substrate processing process or gas remaining in the substrate processing space 13 may be discharged to the outside.

The process gas supply unit 30 may supply a process gas to the interior of the process chamber 10, and the plasma generation unit 50 may form an electromagnetic field in the process chamber 10 to excite the process gas supplied to the interior of the process chamber 10 to a plasma state.

The shower head 40 may be disposed in an upper area in the substrate processing space 13, and may supply the process gas supplied from the process gas supply unit 30 to the substrate processing space 13 in a diffused manner.

The plasma generation unit 50 may excite the process gas in the substrate processing space 13 to a plasma state. In an example, the plasma generation unit 50 may include an antenna 51 provided on the upper side of the chamber 11 and a power supply 55.

The antenna 51 may be disposed parallel to an electrode plate 130 of an electrostatic chuck 110 with the substrate processing space 13 interposed therebetween. An electric field may be formed in the space between the two electrodes, and the process gas supplied to this space may be excited to a plasma state.

The substrate support device 100 may be mounted in the chamber main body 11. The substrate support device 100 may be disposed in a lower area in the substrate processing space 13, and may support the substrate S. The substrate support device 100 may be located at a height spaced upward from the bottom of the chamber main body 11.

The substrate support device 100 may include an electrostatic chuck 110 and a base plate 150.

The electrostatic chuck 110 may include a dielectric plate 120 and an electrode plate 130.

The dielectric plate 120 may chuck the substrate S using electrostatic force to support the same. The periphery of the dielectric plate 120 may be surrounded by a focus ring 140.

The dielectric plate 120 may be located on the top of the electrode plate 130. The dielectric plate 120 may be provided as a disc-shaped dielectric substance. The substrate S may be placed on the upper surface of the dielectric plate 120. In an example, a wafer may be placed as the substrate.

The upper surface of the dielectric plate 120 may have a smaller radius than the substrate S. Therefore, the edge area of the substrate S may be located outside the dielectric plate 120. The edge of the substrate S may be placed on the upper surface of the focus ring 140.

The focus ring 140 may be disposed around the edge area of the dielectric plate 120. The focus ring 140 may have a ring shape, and may be disposed along the circumference of the dielectric plate 120. The outer portion of the focus ring 140 may be provided to surround the edge area of the substrate S. The focus ring 140 may control the electromagnetic field so that the density of plasma is uniformly distributed over the entire area of the substrate S. Accordingly, plasma may be formed uniformly over the entire area of the substrate S, so that respective areas of the substrate S may be uniformly etched.

The dielectric plate 120 may include therein an electrostatic electrode 121, a heater 125, and a supply flow path 133. The supply flow path 133 may be formed through the dielectric plate 120 from the lower surface of the dielectric plate 120 to the upper surface of the dielectric plate 120. The supply flow path 133 may be provided in plural, and the plurality of supply flow paths 133 may be spaced apart from each other. The supply flow paths 133 may serve as passages through which a heat transfer medium is supplied to the lower surface of the substrate S.

The electrostatic electrode 121 may be electrically connected to a first power supply 123. The first power supply 123 may selectively supply direct current power to the electrostatic electrode 121. Electrostatic force may act between the electrostatic electrode 121 and the substrate S due to the current applied to the electrostatic electrode 121, and the substrate S may be adsorbed to the dielectric plate 120 by the electrostatic force.

The heater 125 may be located below the electrostatic electrode 121. The heater 125 may be electrically connected to a second power supply 127. The heater 125 may generate resistive heat upon receiving a current applied thereto from the second power supply 127. The generated heat may be transferred to the substrate S through the dielectric plate 120. The substrate S may be maintained at a predetermined temperature by the heat generated by the heater 125. The heater 125 may include a spiral-shaped coil.

The electrode plate 130 may be located under the dielectric plate 120. The lower surface of the dielectric plate 120 and the upper surface of the electrode plate 130 may be adhered to each other using an adhesive. The electrode plate 130 may be made of aluminum. The electrode plate 130 may have an area corresponding to the dielectric plate 120, and may be adhered to the lower surface of the dielectric plate 120. The electrode plate 130 may include a first flow path 131 and a second flow path 135 formed therein.

The first flow path 131 may serve as a passage through which a heat transfer medium circulates. The first flow path 131 may receive a heat transfer medium from a heat transfer medium supply unit 170 through a fluid supply block 200. In an example, the heat transfer medium may include helium (He).

The heat transfer medium such as helium (He) may be transferred to the supply flow path 133 through the first flow path 131 and may be supplied to the lower surface of the substrate S. The heat transfer medium such as helium may serve as a medium through which heat transferred from the plasma to the substrate S is transferred to the dielectric plate 120.

The second flow path 135 may serve as a passage through which refrigerant circulates. The second flow path 135 may be formed below the first flow path 131. The second flow path 135 may receive coolant from a refrigerant supply unit 190 through the fluid supply block 200.

The coolant supplied to the second flow path 135 may circulate along the second flow path 135 to cool the electrode plate 130. As the electrode plate 130 is cooled, the dielectric plate 120 and the substrate S may also be cooled, and thus the substrate S may be maintained at a predetermined temperature.

In an example, the coolant may be cooled to a low temperature before being supplied. For example, the coolant may be cooled to −70° C. or lower (ultra-low temperature). Preferably, the temperature of the coolant may be controlled within the range of room temperature to −70° C.

The base plate 150 may be located under the electrostatic chuck 110 to support the electrostatic chuck 110.

The base plate 150 may be provided with a fluid supply block 200 that supplies temperature control fluid and coolant to the electrostatic chuck 110. In this embodiment, the fluid supply block 200 is shown and described as being mounted in the base plate 150. However, in some embodiments, the fluid supply block 200 may be disposed in contact with the lower surface of the base plate 150.

The fluid supply block 200 according to the present invention is equipped with sealing members 300 and 400, which actively expand to enhance adhesion, thereby preventing leakage of the temperature control fluid.

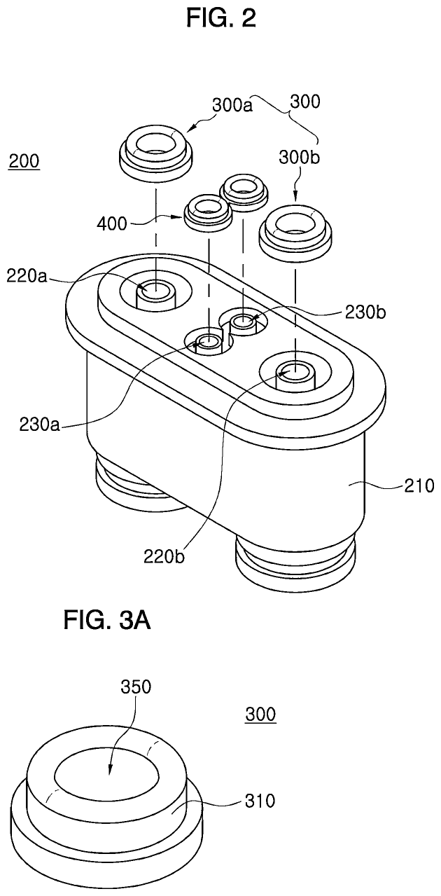

FIG. 2 shows an embodiment of the fluid supply block of the substrate support device according to the present invention.

The fluid supply block 200 may supply a heat transfer medium and coolant as the temperature control fluid.

The fluid supply block 200 may include a body 210 and temperature control fluid supply paths 220a, 220b, 230a, and 230b. The temperature control fluid supply paths may include heat transfer medium supply paths 220a and 220b and coolant supply paths 230a and 230b.

The body 210 may be mounted in the base plate 150. The body 210 may be made of a material such as, for example, PEEK. The shape of the body 210 may vary depending on situations.

The heat transfer medium supply paths 220a and 220b and the coolant supply paths 230a and 230b may be provided in the body 210.

One of the heat transfer medium supply paths 220a and 220b may be a heat transfer medium inlet 220a, which receives the heat transfer medium such as helium from the heat transfer medium supply unit 170 and supplies the same to the first flow path 131 of the electrostatic chuck 110. The other of the heat transfer medium supply paths 220a and 220b may be a heat transfer medium outlet 220b, which receives the heat transfer medium such as helium discharged from the first flow path 131 of the electrostatic chuck 110 and discharges the same to the heat transfer medium supply unit 170.

In this embodiment, the heat transfer medium inlet 220a and the heat transfer medium outlet 220b are shown as being spaced apart from each other. However, in some embodiments, the heat transfer medium inlet 220a and the heat transfer medium outlet 220b may be located adjacent to each other.

One of the coolant supply paths 230a and 230b may be a coolant inlet 230a, which receives the coolant from the refrigerant supply unit 190 and supplies the same to the second flow path 135 of the electrostatic chuck 110. The other of the coolant supply paths 230a and 230b may be a coolant outlet 230b, which receives the coolant discharged from the second flow path 135 of the electrostatic chuck 110 and discharges the same to the refrigerant supply unit 190.

In this embodiment, the coolant inlet 230a and the coolant outlet 230b are shown as being located adjacent to each other. However, in some embodiments, the coolant inlet 230a and the coolant outlet 230b may be spaced apart from each other.

Further, although the fluid supply block 200 is shown as including one heat transfer medium inlet 220a, one heat transfer medium outlet 220b, one coolant inlet 230a, and one coolant outlet 230b, the number of heat transfer medium/coolant inlets and outlets may be varied as needed.

The sealing members 300 and 400 for preventing leakage of fluid may be mounted to the heat transfer medium inlet 220a, the heat transfer medium outlet 220b, the coolant inlet 230a, and the coolant outlet 230b.

In the present invention, the sealing members 300 and 400 may actively expand and thus change in volume according to injection of air.

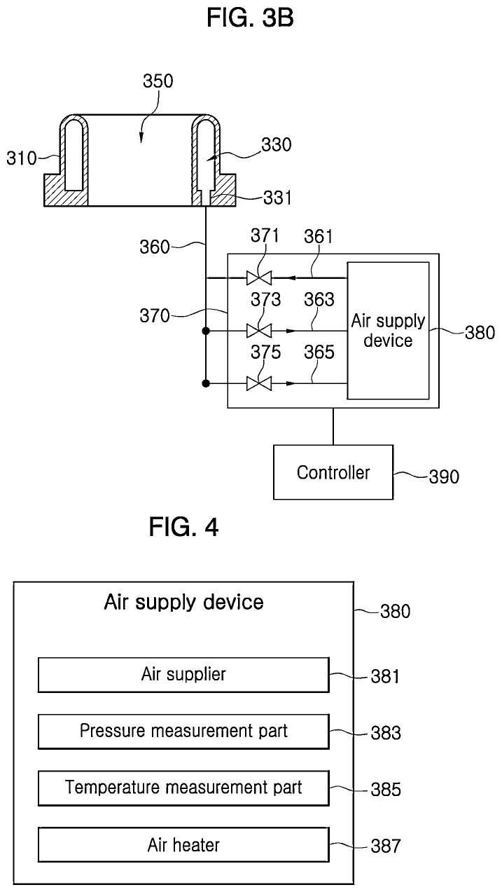

FIGS. 3A and 3B show an embodiment of the sealing member according to the present invention.

In this embodiment, the sealing member 300 may be a first sealing member that is applied when the inlet and the outlet, each of which is to be equipped with the sealing member, are spaced apart from each other by a predetermined distance or more. In the embodiment shown in FIG. 2, if the heat transfer medium inlet 220a and the heat transfer medium outlet 220b, which are temperature control fluid supply paths, are located on the fluid supply block 200 so as to be spaced apart from each other, the sealing member 300 may be individually mounted to each of the heat transfer medium inlet 220a and the heat transfer medium outlet 220b.

The sealing member 300 may include a sealing body 310 made of a flexible material such as rubber or silicon, and the sealing body 310 may be formed as a circular ring. The shape of the sealing body 310 may vary corresponding to the shape of a portion to which the sealing body 310 is mounted.

The sealing body 310 may include a through-hole 350 formed through the central portion thereof, and an end portion of the heat transfer medium inlet 220a or the heat transfer medium outlet 220b may be fitted into a portion of the through-hole 350. In addition, an inlet or an outlet of the first flow path 131 of the electrostatic chuck 110 may be fitted into the remaining portion of the through-hole 350 in the sealing body 310.

The sealing body 310 may include an air injection space 330 defined therein. The air injection space 330 may be formed corresponding to the circular ring shape of the sealing body 310.

As air is injected into the air injection space 330, the sealing body 310 may expand. Although the sealing body 310 is described as expanding due to injection of air into the air injection space 330, the sealing body 310 may also expand due to injection of gas other than air into the air injection space 330. In an example, an inert gas that is not explosive or reactive may be used in place of air.

The sealing body 310 may be provided in one side thereof with an air injection port 331 that is connected to the air injection space 330, and the air injection port 331 may be connected to an air movement path 360.

The air movement path 360 may be connected to an air supply unit 370 to supply air supplied from the air supply unit 370 to the air injection space 330 in the sealing member 300.

The air movement path 360 may include a supply air movement path 361, a control air movement path 363, and a discharge air movement path 365, which diverge therefrom.

The air supply unit 370 may include air injection control valves 371, 373, and 375 and an air supply device 380.

The air supply device 380 may supply air to the sealing member 300 through the air movement path 360 or may discharge air from the sealing member 300. Preferably, the air supply device 380 may include an air pressure pump to control the air pressure, thereby supplying or suctioning air.

The air movement paths 361, 363, and 365 may be provided with air control valves 371, 373, and 375 in order to control movement of air.

The supply air movement path 361 may be provided with an air injection control valve 371 in order to control the air supplied to the sealing member 300 through the supply air movement path 361.

The control air movement path 363 may be provided with an air pressure control valve 373 in order to control the pressure of the air supplied to the sealing member 300. If air pressure having a predetermined level or greater is applied to the sealing member 300, the air pressure control valve 373 may discharge air through the control air movement path 363, thereby controlling the air pressure in the sealing member 300.

The discharge air movement path 365 may be provided with an air discharge control valve 375 in order to control discharge of the air injected into the sealing member 300.

The air supply device 380 may supply air to the air movement path 360 or may discharge air from the air movement path 360.

A controller 390 may control the air supply unit 370 to actively control the volume of the sealing member 300.

In an example, as the process is performed, the controller 390 may control, based on a difference between the temperature of the electrostatic chuck 110 and the temperatures of the base plate 150 and the fluid supply block 200, the air supply unit 370 to actively control the volume of the sealing member 300.

In particular, the controller 390 may selectively expand the volume of the sealing member 300, thereby enhancing adhesion of the sealing member 300, thus ensuring stable sealing.

Further, the air supply device 380 may control the pressure and temperature of the air and supply the air under the control of the controller 390.

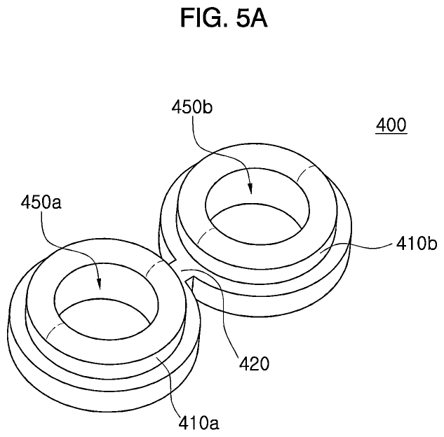

In this regard, FIG. 4 shows a configuration diagram of an embodiment of the air supply device of the substrate support device according to the present invention.

The air supply device 380 may include an air supplier 381, a pressure measurement part 383, a temperature measurement part 385, and an air heater 387.

The air supplier 381 may include an air pressure pump and may control the pressure of the air and supply the air under the control of the controller 390.

The pressure measurement part 383 may measure the pressure of the air supplied through the air supply device 380, and the controller 390 may control the amount, pressure, and temperature of the air supplied to the sealing member 300 based on the result of measuring the pressure of the air supplied.

The temperature measurement part 385 may measure the temperature of the air supplied through the air supply device 380, and the controller 390 may control the amount, pressure, and temperature of the air supplied to the sealing member 300 based on the result of measuring the temperature of the air supplied.

The air heater 387 may include a heating coil and may control the temperature of the air and supply the air under the control of the controller 390.

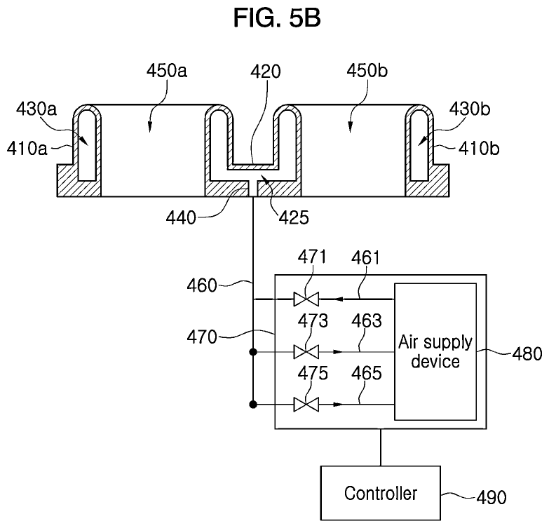

FIGS. 5A and 5B show another embodiment of the sealing member according to the present invention.

In this embodiment, the sealing member 400 may be a second sealing member that is applied when the inlet and the outlet, each of which is to be equipped with the sealing member, are adjacent to each other by a predetermined distance or less. In the embodiment shown in FIG. 2, if the coolant inlet 230a and the coolant outlet 230b, which are coolant fluid supply paths 230a and 230b, are located on the fluid supply block 200 so as to be adjacent to each other, the sealing member 400 may be an integrated sealing member that is mounted to both the coolant inlet 230a and the coolant outlet 230b.

The sealing member 400 may include a first sealing portion 410a and a second sealing portion 410b, which are made of a flexible material such as rubber or silicon, and may include a connection portion 420 formed between the first sealing portion 410a and the second sealing portion 410b, so that the first sealing portion 410a, the second sealing portion 410b, and the connection portion 420 may be integrally formed with each other.

The first sealing portion 410a may include a first through-hole 450a formed through the central portion thereof, and the second sealing portion 410b may include a second through-hole 450b formed through the central portion thereof.

An end portion of the coolant inlet 230a may be fitted into a portion of the first through-hole 450a in the first sealing portion 410a, and an inlet of the second flow path 135 of the electrostatic chuck 110 may be fitted into the remaining portion of the first through-hole 450a in the first sealing portion 410a.

In addition, an end portion of the coolant outlet 230b may be fitted into a portion of the second through-hole 450b in the second sealing portion 410b, and an outlet of the second flow path 135 of the electrostatic chuck 110 may be fitted into the remaining portion of the second through-hole 450b in the second sealing portion 410b.

The first sealing portion 410a may include a first air injection space 430a defined therein, and the second sealing portion 410b may include a second air injection space 430b defined therein. The first air injection space 430a and the second air injection space 430b may be formed in a circular ring shape corresponding to the first sealing portion 410a and the second sealing portion 410b.

As air is injected into the first air injection space 430a and the second air injection space 430b, the first sealing portion 410a and the second sealing portion 410b may expand.

The connection portion 420 may include a connection space 425 defined therein. The connection space 425 in the connection portion 420 may be connected to the first air injection space 430a and the second air injection space 430b.

The connection portion 420 may be provided in one side thereof with an air injection port 440 that is connected to the connection space 425, and the air injection port 440 may be connected to an air movement path 460.

The air movement path 460 may be connected to an air supply unit 470 to supply air supplied from the air supply unit 470 to the first air injection space 430a and the second air injection space 430b in the sealing member 400.

The air movement path 460 may include a supply air movement path 461, a control air movement path 463, and a discharge air movement path 465, which diverge therefrom. The air supply unit 470 may include air injection control valves 471, 473, and 475 and an air supply device 480. A controller 490 may control the air supply unit 470 to actively control the volume of the sealing member 400.

Since the configurations and functions of the air supply unit 470 and the controller 490 can be inferred through the above-described embodiment, a detailed description thereof will be omitted.

In addition, the present invention proposes a method of controlling prevention of leakage of temperature control fluid in the substrate support device described above. A method of controlling prevention of leakage of temperature control fluid according to an embodiment of the present invention will be described.

Since the method of controlling prevention of leakage of temperature control fluid according to the present invention is implemented in the above-described substrate support device according to the present invention, the method will be described with reference to the above embodiment of the substrate support device.

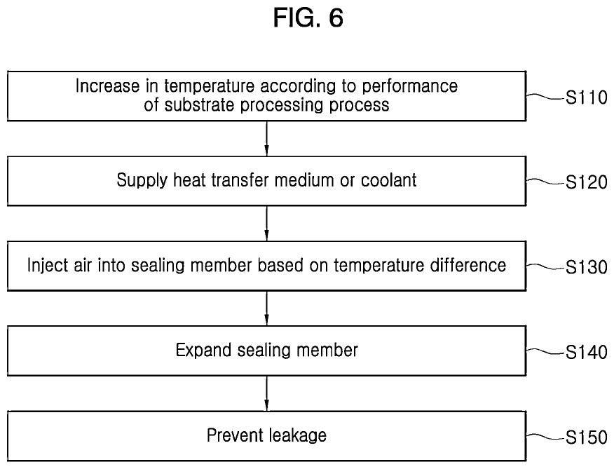

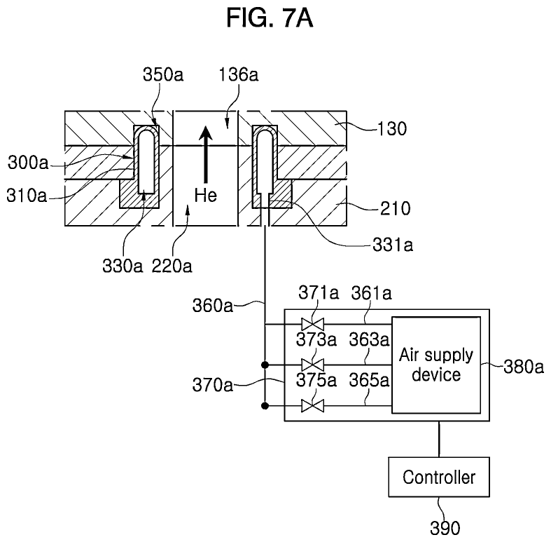

FIG. 6 shows a flowchart of an embodiment of the method of controlling prevention of leakage of temperature control fluid according to the present invention.

As the substrate processing process is performed, the temperatures of the electrostatic chuck 110 and the substrate S may change suddenly (S110). If a heat transfer medium, such as helium (He), or coolant is supplied as the temperature control fluid, the temperatures may change more suddenly.

If a heat transfer medium or coolant is supplied through the fluid supply block 200 in order to control the temperature of the electrostatic chuck 110 or the substrate S or cool the same (S120), gaps may be created due to a difference in coefficient of expansion between the electrostatic chuck 110 and the fluid supply block 200 and a difference in coefficient of expansion between the fluid supply block 200 and the sealing members 300 and 400, which may cause leakage of the heat transfer medium or the coolant.

The present invention actively expands the sealing members to enhance adhesion of the sealing members, thereby suppressing creation of gaps and thus preventing leakage of the temperature control fluid.

The controllers 390 and 490 determine a temperature difference as the substrate processing process is performed. The controllers 390 and 490 may determine, in advance, the temperatures of the electrostatic chuck 110, the fluid supply block 200, and the sealing members 300 and 400 according to performance of each process, may store temperature difference data, and may determine a temperature difference according to performance of the corresponding process based thereon. Alternatively, a temperature measurement part for measuring the temperatures of the electrostatic chuck 110, the fluid supply block 200, and the sealing members 300 and 400 may be provided, and the controllers 390 and 490 may determine a temperature difference based on the temperatures measured by the temperature measurement part.

In addition, the controllers 390 and 490 may determine a temperature change based on the coefficients of expansion of the fluid supply block 200 and the sealing members 300 and 400 depending on temperature.

The controller 390 may set, based on the temperature difference, conditions for the amount of air injected and the pressure of air injected in order to expand the sealing member 300.

In addition, the controller 390 may control the air supply unit 370 to control the amount of air injected and the pressure of air injected and to inject the air into the air injection space 330 in the sealing member 300 (S130).

As the air is injected thereinto, the sealing member 300 may expand (S140), and may fill the gap between the sealing member 300 and the fluid supply block 200, and thus adhesion of the sealing member 300 may be enhanced.

Accordingly, leakage of the temperature control fluid may be prevented (S150).

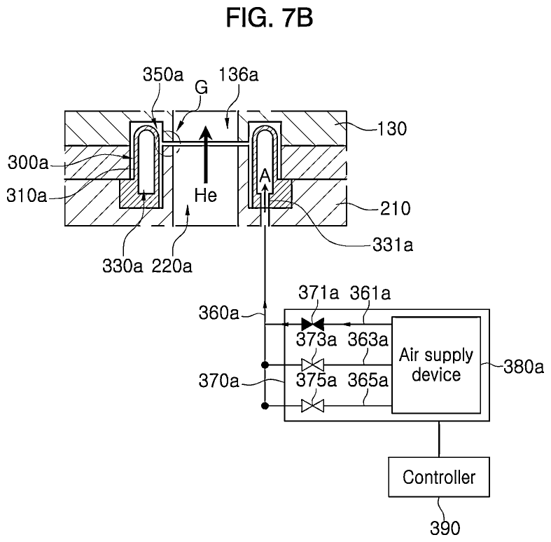

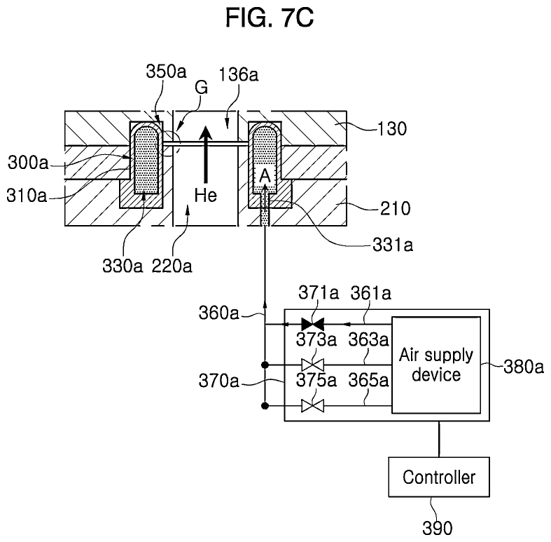

The method of controlling prevention of leakage of temperature control fluid according to the present invention will be described in more detail with reference to FIGS. 7A to 9C.

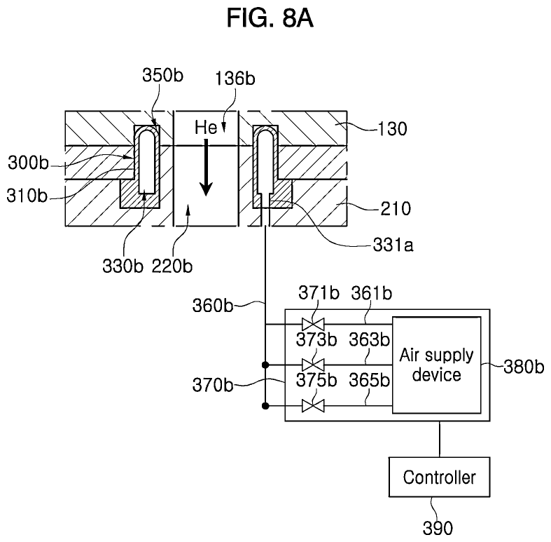

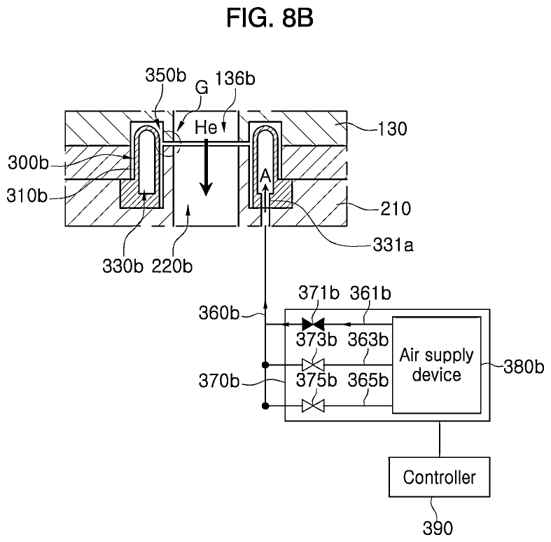

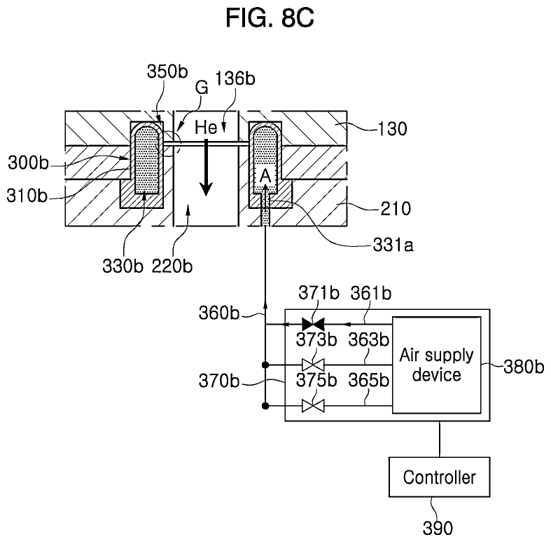

With regard to a process of controlling prevention of leakage of the temperature control fluid, FIGS. 7A to 7C show an embodiment of the leakage prevention control process when a heat transfer medium as the temperature control fluid is supplied in the method of controlling prevention of leakage of temperature control fluid according to the present invention, and FIGS. 8A to 8C show an embodiment of the leakage prevention control process when the heat transfer medium as the temperature control fluid is discharged in the method of controlling prevention of leakage of temperature control fluid according to the present invention.

In relation to the situation in which the heat transfer medium as the temperature control fluid is supplied to the electrostatic chuck, if helium, which is the heat transfer medium, is supplied to an inlet 136a of the first flow path through a heat transfer medium inlet 220a of the fluid supply block as shown in FIG. 7A, a gap G may be created due to a difference in coefficient of expansion between a body 210 of the fluid supply block and a sealing member 300a as shown in FIG. 7B.

The controller 390 may open an air injection control valve 371a disposed on a supply air movement path 361a, and may control an air supply device 380a to supply air to an air movement path 360a.

The air in the air movement path 360a may be injected into an air injection space 330a in the sealing member 300a to expand the sealing member 300a.

As shown in FIG. 7C, the gap between the fluid supply block 200 and the sealing member 300a may be filled due to expansion of the sealing member 300a, and thus adhesion of the sealing member 300a may be enhanced. Accordingly, it may be possible to prevent leakage of helium, which is the heat transfer medium.

In relation to the situation in which the heat transfer medium as the temperature control fluid is discharged from the electrostatic chuck, if helium, which is the heat transfer medium, is discharged from an outlet 136b of the first flow path through a heat transfer medium outlet 220b of the fluid supply block as shown in FIG. 8A, a gap G may be created due to a difference in coefficient of expansion between the body 210 of the fluid supply block and a sealing member 300b as shown in FIG. 8B.

The controller 390 may open an air injection control valve 371b disposed on a supply air movement path 361b, and may control an air supply device 380b to supply air to an air movement path 360b.

The air in the air movement path 360b may be injected into an air injection space 330b in the sealing member 300b to expand the sealing member 300b.

As shown in FIG. 8C, the gap between the fluid supply block 200 and the sealing member 300b may be filled due to expansion of the sealing member 300b, and thus adhesion of the sealing member 300b may be enhanced. Accordingly, it may be possible to prevent leakage of helium, which is the heat transfer medium.

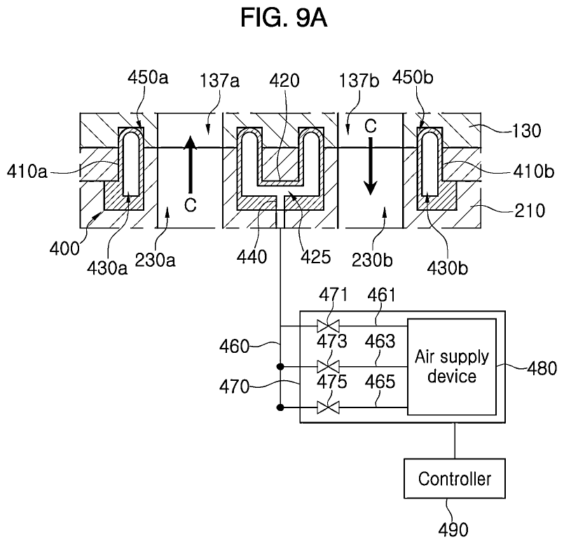

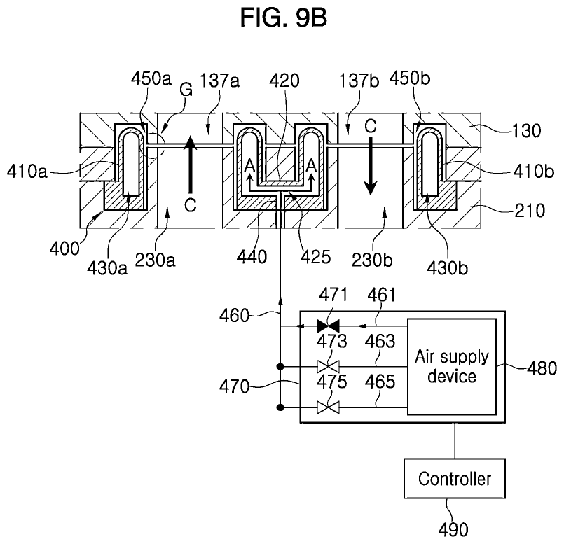

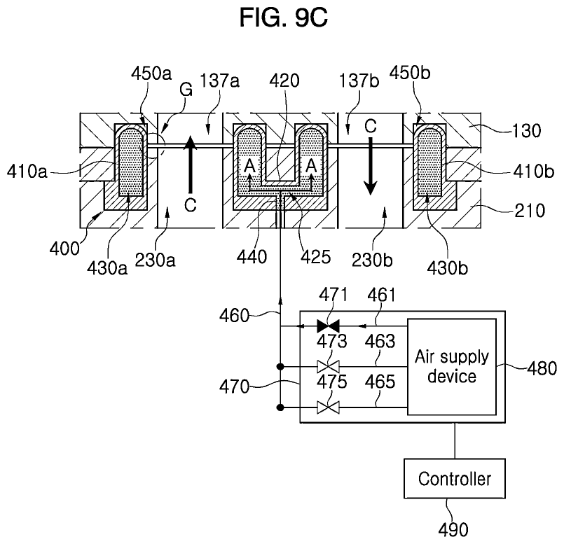

Next, with regard to the process of controlling prevention of leakage of the temperature control fluid, FIGS. 9A to 9C show an embodiment of the leakage prevention control process when coolant as the temperature control fluid is supplied and discharged in the method of controlling prevention of leakage of temperature control fluid according to the present invention.

In relation to the situation in which the coolant as the temperature control fluid is supplied to and discharged from the electrostatic chuck, if the coolant is supplied to an inlet 137a of the second flow path through a coolant inlet 230a of the fluid supply block and the coolant having circulated through the second flow path is discharged through an outlet 137b of the second flow path as shown in FIG. 9A, a gap G may be created due to a difference in coefficient of expansion between the body 210 of the fluid supply block and a sealing member 400 as shown in FIG. 9B.

The controller 490 may open an air: injection control valve 471 disposed on a supply air movement path 461, and may control an air supply device 480 to supply air to an air movement path 460.

The air in the air movement path 460 may be injected into a connection space 425 defined in a connection portion 420 of the sealing member 400, and the injected air may be supplied to a first air injection space 440a in a first sealing portion 410a and a second air injection space 440b in a second sealing portion 410b through the connection space 425.

The air injected into the first air injection space 440a may expand the first sealing portion 410a, and the air injected into the second air injection space 440b may expand the second sealing portion 410b.

As shown in FIG. 9C, the gap between the fluid supply block 200 and the sealing member 400 may be filled due to expansion of the sealing member 400, and thus adhesion of the sealing member 400 may be enhanced. Accordingly, it may be possible to prevent leakage of the coolant.

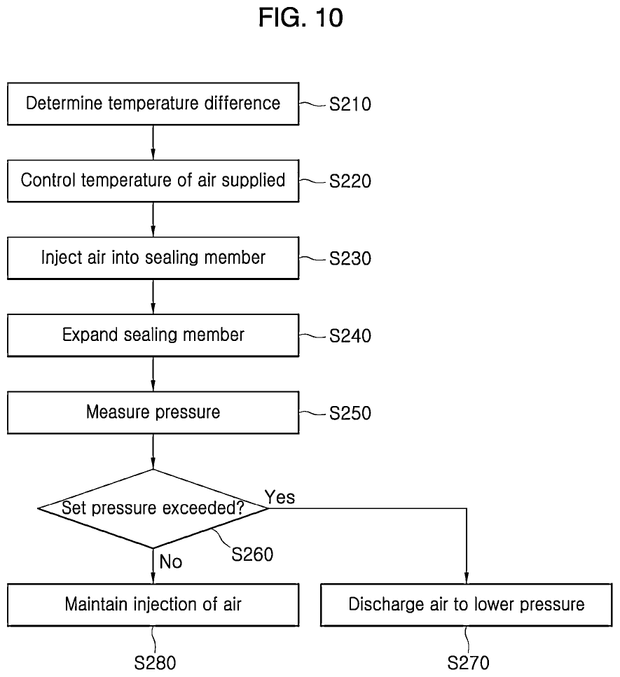

FIG. 10 shows a flowchart of another embodiment of the method of controlling prevention of leakage of temperature control fluid according to the present invention.

In describing this embodiment, description of the same parts as those of the previous embodiment described with reference to FIG. 6 will be omitted or briefly given below.

As the substrate processing process is performed, the controllers 390 and 490 may determine a difference in temperature between the electrostatic chuck 110 and the fluid supply block 200 or a difference in temperature between the fluid supply block 200 and the sealing members 300 and 400 (S210).

The controllers 390 and 490 may control, based on the temperature difference, the air supply devices 380 and 480 of the air supply units 370 and 470 to control the temperature of air to be supplied (S220).

In addition, the controllers 390 and 490 may set, based on the temperature difference, the injection amount and the pressure of air to be supplied, and may control the air supply units 370 and 470 to inject air into the sealing members 300 and 400 (S230).

If the sealing members 300 and 400 expand due to injection of air thereinto (S240), the controllers 390 and 490 may acquire an air pressure measurement value (S250), and may determine whether the air pressure measurement value exceeds a set pressure range (S260). Here, the set pressure range may be set to a range that allows the sealing members 300 and 400 to expand to achieve appropriate sealing. The set pressure range may be set based on a temperature difference, an amount of air injected, temperature of air, and the like.

If the air pressure in the sealing members 300 and 400 exceeds the set pressure range, the controllers 390 and 490 may control the air supply units 370 and 470 to discharge air from the sealing members 300 and 400 to lower the air pressure (S270).

If the air pressure in the sealing members 300 and 400 is lower than the set pressure range, the controllers 390 and 490 may control the air supply units 370 and 470 to increase the air pressure in the sealing members 300 and 400.

If the air pressure in the sealing members 300 and 400 is within the set pressure range, the controllers 390 and 490 may control the air supply units 370 and 470 to maintain injection of air so that the air pressure follows the set pressure range (S280).

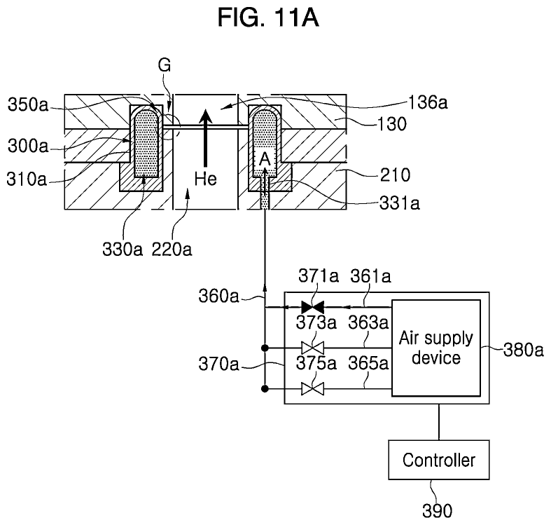

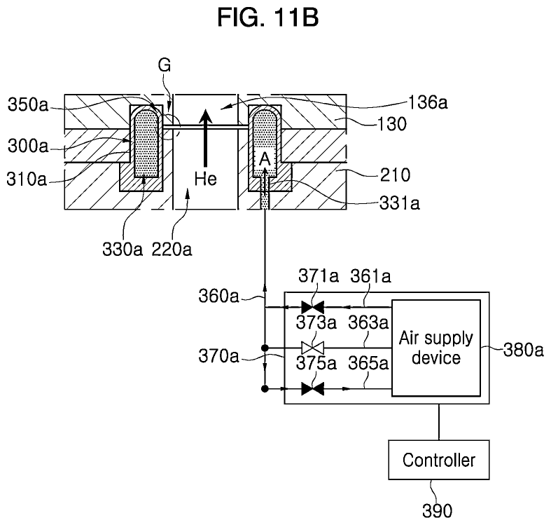

FIGS. 11A and 11B show an embodiment of a process of controlling the air pressure in the sealing member in the method of controlling prevention of leakage of temperature control fluid according to the present invention.

As shown in FIG. 11A, if helium, which is the heat transfer medium, is supplied to the inlet 136a of the first flow path through the heat transfer medium inlet 220a of the fluid supply block, the controller 390 may open the air injection control valve 371a disposed on the supply air movement path 361a, and may control the air supply device 380a to supply air to the air movement path 360a.

While supplying air to expand the sealing member 300a, the controller 390 may determine the degree of expansion of sealing member 300a based on the air pressure measurement value.

If the air pressure in the sealing member 300a exceeds the set pressure range, the controller 390 may control the air pressure control valve 373b disposed on the control air movement path 363b to discharge a certain amount of air from the sealing member 300a as shown in FIG. 11B.

If the air pressure in the sealing member 300a is within the set pressure range, the controller 390 may close the air pressure control valve 373b to maintain the air pressure in the sealing member 300a.

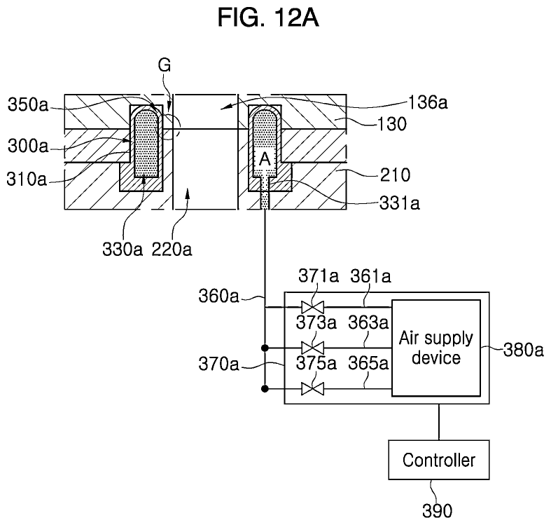

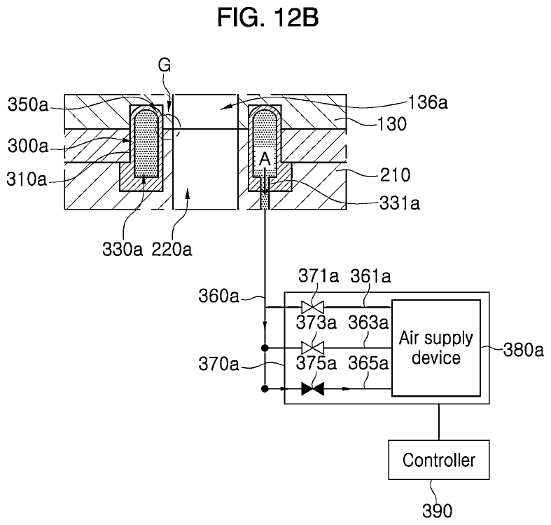

FIGS. 12A and 12B show an embodiment of a process of discharging air from the sealing member in the method of controlling prevention of leakage of temperature control fluid according to the present invention.

In the state in which a difference in temperature between the electrostatic chuck 110 and the fluid supply block 200 or a difference in temperature between the fluid supply block 200 and the sealing members 300 and 400 is maintained at a predetermined level or less and thus no gap is created, if the sealing member 300a is maintained in an expanded state, stress may be continuously accumulated in the sealing member 300a.

Therefore, if a difference in temperature between the electrostatic chuck and the fluid supply block or a difference in temperature between the fluid supply block and the sealing members is eliminated and thus no gap is created as shown in FIG. 12A, the controller 390 may open the air discharge control valve 375a disposed on the discharge air movement path 365a to discharge air from the sealing member 300a through the air supply device 380a as shown in FIG. 12B.

As described above, the present invention employs a sealing member that is actively controlled in volume expansion taking into consideration a difference in coefficient of expansion supply block supplying the heat transfer medium or the coolant as the temperature control fluid and the electrostatic chuck due to different materials thereof or a difference in coefficient of expansion between the fluid supply block and the sealing member due to different materials thereof in the substrate support device, thereby preventing leakage of the temperature control fluid.

In particular, in the state in which temperature changes suddenly as the substrate processing process is performed and thus a gap is created due to a difference in expansion between the fluid supply block and the electrostatic chuck or between the fluid supply block and the sealing member, the present invention actively expands the sealing member to enhance adhesion of the sealing member, thereby ensuring stable sealing and thus preventing leakage of the temperature control fluid.

As is apparent from the above description, the present invention provides technology for preventing leakage of temperature control fluid by employing a sealing member that is actively controlled in volume expansion taking into consideration a difference in coefficient of expansion between a fluid supply block supplying a heat transfer medium or coolant as the temperature control fluid and an electrostatic chuck due to different materials thereof or a difference in coefficient of expansion between the fluid supply block and the sealing member due to different materials thereof in a substrate support device.

In particular, the present invention provides technology for actively expanding the sealing member to enhance adhesion of the sealing member in the state in which temperature changes suddenly as a substrate processing process is performed and thus a gap is created due to a difference in expansion between the fluid supply block and the electrostatic chuck or between the fluid supply block and the sealing member, thereby ensuring stable sealing and thus preventing leakage of the temperature control fluid.

The effects achievable through the present invention are not limited to the above-mentioned effects, and other effects not mentioned herein will be clearly understood by those skilled in the art from the above description.

It will be apparent to those skilled in the art that various changes in form and details may be made without departing from the essential characteristics of the invention set forth herein. Accordingly, the above detailed description is not intended to be construed to limit the invention in all aspects and to be considered by way of example. The scope of the invention should be determined by reasonable interpretation of the appended claims and all equivalent modifications made without departing from the invention should be included in the following claims.

What is claimed is:

1. A substrate support device comprising:
an electrostatic chuck configured to support a substrate, the electrostatic chuck comprising therein a flow path of temperature control fluid for temperature control;
a body member configured to support the electrostatic chuck;
a fluid supply block mounted in the body member, the fluid supply block comprising a temperature control fluid supply path formed therein to supply the temperature control fluid to the flow path in the electrostatic chuck;
a sealing member mounted to the fluid supply block, the sealing member comprising an air injection space defined therein, the sealing member being configured to expand due to injection of air into the air injection space; and
an air supply unit configured to inject air into the sealing member.

2. The substrate support device according to claim 1, further comprising a controller configured to control, based on a difference in temperature between the electrostatic chuck and the fluid supply block or a difference in temperature between the fluid supply block and the sealing member, the air supply unit to inject air into the sealing member to expand the sealing member.

3. The substrate support device according to claim 2, wherein the air supply unit comprises:
an air movement path configured to supply air to the sealing member;
an air supply device configured to supply air to the air movement path; and
an air injection control valve disposed on the air movement path to control supply of air.

4. The substrate support device according to claim 3, wherein the air supply unit further comprises a pressure measurement part configured to measure pressure of air supplied through the air movement path, and
wherein the controller controls injection of air into the sealing member based on a pressure value measured by the pressure measurement part.

5. The substrate support device according to claim 4, wherein the air supply unit further comprises:
a supply air movement path configured to supply air to the sealing member;
an air injection control valve disposed on the supply air movement path to control supply of air to be injected;
a control air movement path configured to control air pressure in the sealing member;
an air pressure control valve disposed on the control air movement path to control pressure of air supplied to the sealing member;
a discharge air movement path configured to discharge air from the sealing member; and
an air discharge control valve disposed on the discharge air movement path to control discharge of air from the sealing member.

6. The substrate support device according to claim 3, wherein the air supply unit further comprises an air heater configured to control temperature of air to be supplied, and
wherein the controller controls the air heater to control temperature of air to be injected according to a degree of expansion of the sealing member.

7. The substrate support device according to claim 1, wherein the fluid supply block comprises:
a heat transfer medium inlet configured to supply a heat transfer medium to the electrostatic chuck; and
a heat transfer medium outlet configured to discharge the heat transfer medium from the electrostatic chuck, and
wherein the sealing member comprises:
a sealing member mounted to the heat transfer medium inlet; and
a sealing member mounted to the heat transfer medium outlet.

8. The substrate support device according to claim 1, wherein the fluid supply block comprises:
a coolant inlet configured to supply coolant to the electrostatic chuck; and
a coolant outlet configured to discharge the coolant from the electrostatic chuck, and
wherein the sealing member comprises:
a first sealing portion fastened to the coolant inlet, the first sealing portion comprising a first air injection space defined therein, the first sealing portion being configured to expand due to injection of air into the first air injection space;
a second sealing portion fastened to the coolant outlet, the second sealing portion comprising a second air injection space defined therein, the second sealing portion being configured to expand due to injection of air into the second air injection space; and
a connection portion configured to interconnect the first sealing portion and the second sealing portion.

9. The substrate support device according to claim 8, wherein the connection portion of the sealing member comprises:
a connection space defined therein to interconnect the first air injection space in the first sealing portion and the second air injection space in the second sealing portion; and
an air injection port connected to the air supply unit to supply air to the connection space or to discharge air from the connection space.

10. The substrate support device according to claim 3, wherein the air supply unit further comprises an air heater configured to control temperature of air supplied through the air movement path, and
wherein the controller controls the air heater to control temperature of air injected into the sealing member.

11. A method of controlling prevention of leakage of temperature control fluid, the method comprising:
a temperature control fluid supply step of supplying, by a fluid supply block, temperature control fluid to control temperature of an electrostatic chuck or a substrate or to cool the electrostatic chuck or the substrate;
an air supply step of supplying, by an air supply unit, air to a sealing member based on a difference in temperature between the electrostatic chuck and the fluid supply block or a difference in temperature between the fluid supply block and the sealing member; and
a sealing step of expanding the sealing member to prevent leakage of the temperature control fluid.

12. The method according to claim 11, wherein the air supply step comprises:
a temperature difference determination step of determining, by a controller, a difference in temperature between the electrostatic chuck and the fluid supply block or a difference in temperature between the fluid supply block and the sealing member;
a condition setting step of setting, by the controller, conditions for an amount and pressure of air injected to expand the sealing member based on the difference in temperature; and
an air injection step of controlling, by the controller, the air supply unit under the set conditions to inject air into the sealing member.

13. The method according to claim 11, wherein the sealing step comprises an air pressure control step of acquiring, by the controller, a pressure measurement value of air injected into the sealing member and controlling, by the controller, the air supply unit based on the pressure measurement value and a set pressure range to control air pressure in the sealing member.

14. The method according to claim 12, wherein, in the temperature control fluid supply step, the fluid supply block supplies a heat transfer medium as the temperature control fluid to a flow path of the electrostatic chuck through a heat transfer medium inlet, and
wherein the air supply step comprises:
a temperature difference determination step of determining, by the controller, a difference in temperature between the electrostatic chuck and the fluid supply block or a difference in temperature between the fluid supply block and the sealing member according to supply of the heat transfer medium;
a condition setting step of setting, by the controller, conditions for one or more of an amount, pressure, and temperature of air injected to expand a sealing member mounted to the heat transfer medium inlet of the fluid supply block based on the difference in temperature according to supply of the heat transfer medium; and
an air injection step of opening, by the controller, an air injection control valve based on the difference in temperature and controlling, by the controller, an air supply device under the set conditions to inject air into the sealing member through a supply air movement path.

15. The method according to claim 14, wherein, in the sealing step, if air pressure in the sealing member exceeds a set pressure range, the controller controls an air pressure control valve disposed on a control air movement path to control air injected into the sealing member.

16. The method according to claim 14, wherein, in the temperature control fluid supply step, the fluid supply block discharges the heat transfer medium as the temperature control fluid from the flow path of the electrostatic chuck through a heat transfer medium outlet, and
wherein the air supply step further comprises:
a temperature step difference determination of determining, by the controller, a difference in temperature between the electrostatic chuck and the fluid supply block or a difference in temperature between the fluid supply block and the sealing member according to discharge of the heat transfer medium;
a condition setting step of setting, by the controller, conditions for one or more of an amount, pressure, and temperature of air injected to expand a sealing member mounted to the heat transfer medium outlet of the fluid supply block based on the difference in temperature according to discharge of the heat transfer medium; and
an air injection step of opening, by the controller, the air injection control valve based on the difference in temperature and controlling, by the controller, the air supply device under the set conditions to inject air into the sealing member through the supply air movement path.

17. The method according to claim 12, wherein, in the temperature control fluid supply step, the fluid supply block supplies coolant as the temperature control fluid to a flow path of the electrostatic chuck through a coolant inlet and discharges the coolant from the flow path of the electrostatic chuck, and
wherein the air supply step comprises:
a temperature difference determination step of determining, by the controller, a difference in temperature between the electrostatic chuck and the fluid supply block or a difference in temperature between the fluid supply block and the sealing member according to supply and discharge of the coolant;
a condition setting step of setting, by the controller, conditions for one or more of an amount, pressure, and temperature of air injected to expand a sealing member mounted to the coolant inlet of the fluid supply block based on the difference in temperature according to supply and discharge of the coolant; and
an air injection step of opening, by the controller, an air injection control valve based on the difference in temperature and controlling, by the controller, an air supply device under the set conditions to inject air into the sealing member through a supply air movement path.

18. The method according to claim 17, wherein, in the air injection step, air is injected into a connection portion of the sealing member, and is supplied to a first sealing portion and a second sealing portion through the connection portion, and
wherein, in the sealing step, the first sealing portion and the second sealing portion expand to prevent leakage of the coolant.

19. The method according to claim 17, wherein, in the sealing step, if air pressure in the sealing member exceeds a set pressure range, the controller controls an air pressure control valve disposed on a control air movement path to control air injected into the first sealing portion and the second sealing portion.

20. A substrate support device comprising:
an electrostatic chuck configured to support a substrate, the electrostatic chuck comprising a first flow path and a second flow path formed therein so as to correspond to a heat transfer medium and coolant as temperature control fluid for temperature control;
a body member configured to support the electrostatic chuck;
a fluid supply block mounted in the body member, the fluid supply block being provided with a temperature control fluid supply path comprising a heat transfer medium supply path, comprising a heat transfer medium inlet and a heat transfer medium outlet to supply and discharge the heat transfer medium to and from the first flow path of the electrostatic chuck, and a coolant supply path, comprising a coolant inlet and a coolant outlet to supply and discharge the coolant to and from the second flow path of the electrostatic chuck;
a sealing member comprising a first sealing member, mounted to each of the heat transfer medium inlet and the heat transfer medium outlet and comprising an air injection space defined therein to be controlled in expansion according to injection of air thereinto, and a second sealing member, comprising a first sealing portion mounted to the coolant inlet and comprising a first air injection space defined therein, a second sealing portion mounted to the coolant outlet and comprising a second air injection space defined therein, and a connection portion interconnecting the first sealing portion and the second sealing portion and comprising a connection space defined therein so as to be connected to the first air injection space and the second air injection space, the sealing member being configured to be controlled in expansion according to injection of air thereinto;
an air supply unit comprising an air movement path, comprising a supply air movement path configured to supply air to the sealing member, a control air movement path configured to control air pressure in the sealing member, and a discharge air movement path configured to discharge air from the sealing member, an air control valve, comprising an air injection control valve disposed on the supply air movement path to control supply of air injected, an air pressure control valve disposed on the control air movement path to control pressure of air supplied to the sealing member, and an air discharge control valve disposed on the discharge air movement path to control discharge of air from the sealing member, and an air supply device, comprising a pressure measurement part configured to measure pressure of air supplied through the air movement path and an air supplier configured to supply air; and
a controller configured to control, based on a difference in temperature between the electrostatic chuck and the fluid supply block or a difference in temperature between the fluid supply block and the sealing member, the air supply unit to inject air into the sealing member to expand the sealing member.
